(19) United States
(12) Patent Application Publication
(10) Pub. No.: US 2025/0201636 A1
(43) Pub. Date: Jun. 19, 2025

(54) METHOD OF INSPECTING GROUP-III ELEMENT NITRIDE SUBSTRATE, METHOD OF PRODUCING GROUP-III ELEMENT NITRIDE SUBSTRATE, AND METHOD OF PRODUCING SEMICONDUCTOR DEVICE

(71) Applicant: NGK INSULATORS, LTD., Nagoya-shi (JP)

(72) Inventors: Yoshitaka KURAOKA, Okazaki-shi (JP); Kentaro NONAKA, Gifu-shi (JP)

(21) Appl. No.: 19/055,127

(22) Filed: Feb. 17, 2025

Related U.S. Application Data
(63) Continuation of application No. PCT/JP2023/016089, filed on Apr. 24, 2023.

(30) Foreign Application Priority Data
Aug. 26, 2022 (JP) 2022-135354

(51) Int. Cl. H01L 21/66; C30B 9/12; C30B 25/18; C30B 29/40; G01N 21/64; G01N 23/2251; H01L 21/02; H01L 21/78; H10D 30/01; H10D 30/47; H10D 62/85

(52) U.S. Cl. CPC H01L 22/12; C30B 9/12; C30B 25/18; C30B 29/406; G01N 21/6489; G01N 23/2251; H01L 21/0242; H01L 21/0254; H01L 21/0262; H01L 21/7813; H10D 30/015; H10D 30/475; H10D 62/8503; G01N 2223/6116

(57) ABSTRACT

Provided is a method of inspecting a Group-III element nitride substrate, the method including: preparing a Group-III element nitride substrate doped with an element except a Group-III element; irradiating the Group-III element nitride substrate with excitation energy; and measuring a half width of a band-edge emission peak of an emission spectrum obtained by the irradiation.

### CROSS-REFERENCE TO RELATED APPLICATIONS

This application is a continuation under 35 U.S.C. 120 of International Application PCT/JP2023/016089 having the International Filing Date of Apr. 24, 2023, and having the benefit of the earlier filing date of Japanese Application No. 2022-135354, filed on Aug. 26, 2022. Each of the identified applications is fully incorporated herein by reference.

### BACKGROUND OF THE INVENTION

### 1. Field of the Invention

One or more embodiments of the present invention relate to a method of inspecting a Group-III element nitride substrate, a method of producing a Group-III element nitride substrate, and a method of producing a semiconductor device.

### 2. Description of the Related Art

A Group-III element nitride has a direct transition wide bandgap, a high dielectric breakdown field, and a high saturation electron speed, and is hence actively developed as, for example, a semiconductor material for a high-frequency/high-power electronic device.

For example, as described in Japanese Patent No. 5451085, the above-mentioned Group-III element nitride is desired to have high resistance depending on the usage.

### SUMMARY OF THE INVENTION

A semiconductor device obtained from the above-mentioned Group-III element nitride substrate having high resistance is insufficient in quality uniformity in some cases, and there is a demand for an improvement in yield.

In view of the foregoing, a primary object of at least one embodiment of the present invention is to provide a Group-III element nitride substrate that can improve the yield of a semiconductor device.
1. According to at least one embodiment of the present invention, there is provided a method of inspecting a Group-III element nitride substrate, the method including: preparing a Group-III element nitride substrate doped with an element except a Group-III element; irradiating the Group-III element nitride substrate with excitation energy; and measuring a half width of a band-edge emission peak of an emission spectrum obtained by the irradiation.
2. In the inspection method according to the above-mentioned item 1, the irradiating the Group-III element nitride substrate with the excitation energy may be performed by irradiation with at least one of ultraviolet light or an electron beam.
3. In the inspection method according to the above-mentioned item 1 or 2, the irradiating the Group-III element nitride substrate with the excitation energy may be performed to a plurality of locations on a main surface of the Group-III element nitride substrate.
4. In the inspection method according to any one of the above-mentioned items 1 to 3, the element except the Group-III element may include a transition element.
5. In the inspection method according to the above-mentioned item 4, the transition element may include at least one of iron or manganese.
6. In the inspection method according to any one of the above-mentioned items 1 to 5, the Group-III element nitride substrate may contain gallium nitride.
7. In the inspection method according to any one of the above-mentioned items 1 to 6, the Group-III element nitride substrate may have a resistivity determined by measuring a time dependent charge amount of 1×10⁵ Ω·cm or more.
8. In the inspection method according to any one of the above-mentioned items 1 to 7, the half width is a full width at half maximum.
9. In the inspection method according to any one of the above-mentioned items 1 to 7, the half width is a half width at half maximum.
10. According to at least one embodiment of the present invention, there is provided a method of producing a Group-III element nitride substrate, the method including: performing the method of inspecting a Group-III element nitride substrate of any one of the above-mentioned items 1 to 7; and selecting the Group-III element nitride substrate based on the half width of the band-edge emission peak.
11. In the production method according to the above-mentioned item 10, the Group-III element nitride substrate having a full width at half maximum of the band-edge emission peak of 6.5 nm or less may be selected.
12. In the production method according to the above-mentioned item 10, the Group-III element nitride substrate having a half width at half maximum on a long-wavelength side of the band-edge emission peak of 4.2 nm or less may be selected.
13. In the production method according to any one of the above-mentioned items 10 to 12, the preparing the Group-III element nitride substrate may include: preparing a seed crystal substrate including a sapphire substrate including an upper surface and a lower surface facing each other, and a seed crystal film to be formed on the upper surface of the sapphire substrate; and growing a Group-III element nitride crystal doped with an element except a Group-III element on the seed crystal film of the seed crystal substrate, and the sapphire substrate may have an off-cut of 0.58° or less.
14. In the production method according to the above-mentioned item 13, the sapphire substrate may have an off-cut of 0.20° or more and 0.42° or less.
15. According to at least one embodiment of the present invention, there is provided a method of producing a semiconductor device, the method including: irradiating a Group-III element nitride substrate doped with an element except a Group-III element with excitation energy, and measuring a half width of a band-edge emission peak of an emission spectrum obtained by the irradiation; forming a channel layer and a barrier layer on the Group-III element nitride substrate to provide a laminated structure; and arranging a source electrode, a drain electrode, and a gate electrode on the laminated structure.
16. In the production method according to the above-mentioned item 15, the Group-III element nitride substrate may be irradiated with energy higher than bandgap energy of a constituent material for the channel layer.
17. In the production method according to the above-mentioned item 15 or 16, a semiconductor device including the Group-III element nitride substrate in which the half width satisfies a predetermined value may be obtained.
18. In the production method according to any one of the above-mentioned items 15 to 17, the laminated structure may be obtained by epitaxial growth.
19. According to at least one embodiment of the present invention, there is provided a Group-III element nitride substrate doped with an element except a Group-III element, the Group-III element nitride substrate having a half width of a band-edge emission peak of an emission spectrum obtained by irradiation with excitation energy of 6.5 nm or less.
20. According to at least one embodiment of the present invention, there is provided a Group-III element nitride substrate doped with an element except a Group-III element, the Group-III element nitride substrate having a half width at half maximum on a long-wavelength side of a band-edge emission peak of an emission spectrum obtained by irradiation with excitation energy of 4.2 nm or less.
21. In the Group-III element nitride substrate according to the above-mentioned item 19 or 20, the Group-III element nitride substrate may contain gallium nitride.
22. In the Group-III element nitride substrate according to any one of the above-mentioned items 19 to 21, the element except the Group-III element may include a transition element.
23. In the Group-III element nitride substrate according to the above-mentioned item 22, the transition element may include at least one of iron or manganese.
24. According to at least one embodiment of the present invention, there is provided a method of producing the Group-III element nitride substrate of any one of the above-mentioned items 19 to 23. The method may include: preparing a seed crystal substrate including a sapphire substrate including an upper surface and a lower surface facing each other, and a seed crystal film to be formed on the upper surface of the sapphire substrate; and growing a Group-III element nitride crystal doped with an element except a Group-III element on the seed crystal film of the seed crystal substrate. The sapphire substrate may have an off-cut of 0.58° or less.
25. In the production method according to the above-mentioned item 24, the Group-III element nitride crystal may be grown by a flux method.

### BRIEF DESCRIPTION OF THE DRAWINGS

FIG. 1 is a schematic sectional view for illustrating the schematic configuration of a Group-III element nitride substrate according to at least one embodiment of the present invention.

FIG. 2 is a plan view of the Group-III element nitride substrate illustrated in FIG. 1.

FIG. 3A is a view for illustrating a production process for a Group-III element nitride substrate according to at least one embodiment of the present invention.

FIG. 3B is a view subsequent to FIG. 3A.

FIG. 3C is a view subsequent to FIG. 3B.

FIG. 4 is a schematic sectional view for illustrating the schematic configuration of a semiconductor device according to at least one embodiment of the present invention.

FIG. 5 is a view for illustrating a method of measuring an emission spectrum of a substrate.

FIG. 6 is an emission spectrum in the vicinity of a band edge of a gallium nitride substrate in Experimental Example 1.

FIG. 7 is an emission spectrum in the vicinity of the band edge of the gallium nitride substrate in Experimental Example 1.

### DESCRIPTION OF THE EMBODIMENTS

Embodiments of the present invention are described below with reference to the drawings. The present invention is not limited to those embodiments. In addition, for clearer illustration, some widths, thicknesses, shapes, and the like of respective portions may be schematically illustrated in the drawings in comparison to the embodiments. However, the widths, the thicknesses, the shapes, and the like are each merely an example, and do not limit the understanding of the present invention.

### A. Group-III Element Nitride Substrate

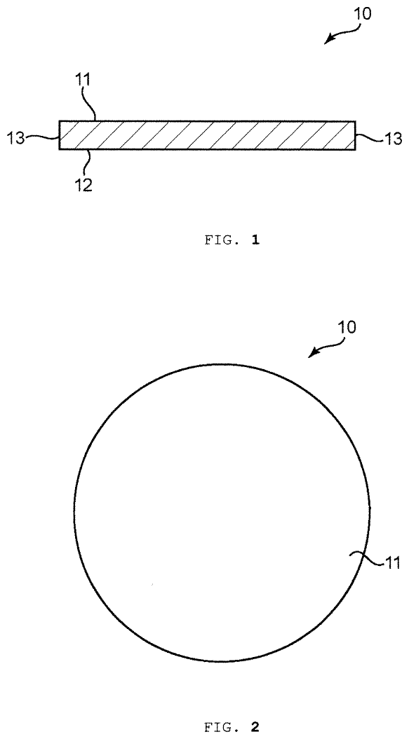

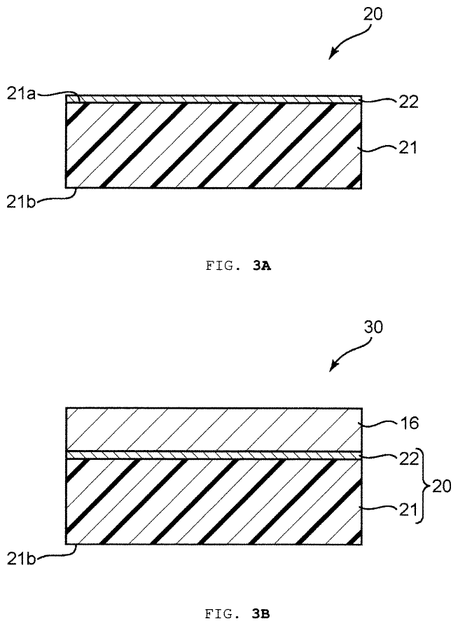

FIG. 1 is a schematic sectional view for illustrating the schematic configuration of a Group-III element nitride substrate according to at least one embodiment of the present invention. FIG. 2 is a plan view of the Group-III element nitride substrate illustrated in FIG. 1. A Group-III element nitride substrate 10 has a plate shape and includes a first main surface 11 and a second main surface 12 facing each other. The main surfaces are linked to each other via a side surface 13.

In the illustrated examples, the Group-III element nitride substrate has a disc shape (wafer), but the shape is not limited thereto and any appropriate shape may be adopted. The size of the Group-III element nitride substrate may be appropriately set in accordance with purposes. The diameter of the Group-III element nitride substrate having a disc shape is, for example, 50 mm or more and 200 mm or less. The thickness of the Group-III element nitride substrate is, for example, 250 μm or more and 800 μm or less.

In at least one embodiment of the present invention, the resistivity of the Group-III element nitride substrate is, for example, 1×10⁵ Ω·cm or more and 1×10¹² Ω·cm or less, preferably 1×10⁶ Ω·cm or more, more preferably 1×10⁷ Ω·cm or more. Such semi-insulating Group-III element nitride substrate may be suitably used as, for example, a substrate for a high-electron-mobility transistor (HEMT) device. Specifically, a channel layer and a barrier layer are formed on the Group-III element nitride substrate, and the resultant may be used as the HEMT device.

The resistivity of the Group-III element nitride substrate may be determined by measuring a time dependent charge amount. By measuring the time dependent charge amount, the resistivity can be determined without breakage of the Group-III element nitride substrate. Specifically, the Group-III element nitride substrate is inserted into a capacitor including a probe and a stage, and a pulse voltage is applied thereto. In this state, the time dependent charge amount of the Group-III element nitride substrate is measured, and the resistivity is calculated from the measured value. In this case, the probe is not brought into contact with the Group-III element nitride substrate, and hence the resistivity can be determined without formation of an ohmic contact electrode. The spatial resolution of the probe may be from about 1 mm to about 10 mm. A method of determining the resistivity is described in, for example, the non-patent literature “R. Stibal et al., “Contactless evaluation of semi-insulating GaAs wafer resistivity using the time-dependent charge measurement,” Semiconductor Science and Technology, 6, pp. 995-1001 (1991).”

The Group-III element nitride substrate includes a Group-III element nitride crystal. For example, aluminum (Al), gallium (Ga), or indium (In) is used as a Group-III element for forming a Group-III element nitride. Those elements may be used alone or in combination thereof. Specific examples of the Group-III element nitride include aluminum nitride (AlₓN), gallium nitride (Ga_{y}N), indium nitride (In_{z}N), aluminum gallium nitride (AlₓGa_{y}N), gallium indium nitride (Ga_{y}In_{z}N), aluminum indium nitride (AlₓIn_{z}N), and aluminum gallium indium nitride (AlₓGa_{y}In_{z}N). In each of the chemical formulae in parentheses, typically, x+y+z=1 is satisfied.

The Group-III element nitride is doped with an element except a Group-III element. Specifically, the Group-III element nitride contains an element except a Group-III element as a dopant. When the Group-III element nitride is doped with an element except a Group-III element, a Group-III element nitride substrate (semi-insulating Group-III element nitride substrate) that may satisfactorily satisfy the above-mentioned resistivity can be obtained. A transition element, such as iron (Fe), manganese (Mn), vanadium (V), chromium (Cr), cobalt (Co), or nickel (Ni), is preferably used as the dopant. Those elements may be used alone or in combination thereof. The transition element preferably includes at least one of iron or manganese.

The presence amount of the transition element in the Group-III element nitride substrate is, for example, 5×10¹⁶ atoms/cm³ or more and 1×10²⁰ atoms/cm³ or less.

In the Group-III element nitride crystal, typically, the <0001> direction is the c-axis direction, the <1-100> direction is the m-axis direction, and the <11-20> direction is the a-axis direction. In addition, the crystal plane perpendicular to the c-axis is the c-plane, the crystal plane perpendicular to the m-axis is the m-plane, and the crystal plane perpendicular to the a-axis is the a-plane. In at least one embodiment of the present invention, the thickness direction of the Group-III element nitride substrate 10 is parallel or approximately parallel to the c-axis, and the first main surface 11 is Group-III element polar surface on (0001) plane side, and the second main surface 12 is nitrogen polar surface on (000-1) plane side. The first main surface 11 may be parallel to the (0001) plane, or may be tilted with respect to the (0001) plane. The angle of the tilt of the first main surface 11 with respect to the (0001) plane is, for example, 10° or less, and may be 5° or less, may be 2° or less, or may be 1° or less. The second main surface 12 may be parallel to the (000-1) plane, or may be tilted with respect to the (000-1) plane. The angle of the tilt of the second main surface 12 with respect to the (000-1) plane is, for example, 10° or less, and may be 5° or less, may be 2° or less, or may be 1° or less.

### B. Inspection Method

It is conceived that, even when the Group-III element nitride substrate has a resistivity determined by measuring a time dependent charge amount satisfying a predetermined value (e.g., 1×10⁵ Ω·cm or more), a region having a low resistivity may be present on the surface of the Group-III element nitride substrate. Specifically, an impurity element such as oxygen may be segregated in a crystal defect such as dislocation in a Group-III element nitride crystal, and this segregation may influence the conductivity. The donor impurity such as oxygen is easily mixed into the crystal defect and may influence the resistivity. For this reason, the case in which the crystal defects are concentrated in a minute region of, for example, from about φ10 μm to about φ200 μm on the surface of the Group-III element nitride substrate is conceived. Meanwhile, the diameter of a measurement probe used in the above-mentioned method of measuring a resistivity by the time dependent charge amount may be, for example, from φ1 mm to φ10 mm. In the measurement of the resistivity by the time dependent charge amount, it is assumed that the resistivity is uniform at least in the range of the diameter of the measurement probe, and hence it is conceived that it is difficult to accurately measure the resistivity of a region that locally includes the minute region having a low resistivity. In addition, a semiconductor device obtained corresponding to a region having a low resistivity may have lower quality. For example, in a HEMT device obtained corresponding to a region having a low resistivity, the leakage of current may occur.

A method of inspecting a Group-III element nitride substrate according to at least one embodiment of the present invention includes: irradiating the prepared Group-III element nitride substrate with excitation energy; and measuring a half width of a band-edge emission peak of an emission spectrum obtained by the irradiation.

The irradiation with the excitation energy may be performed, for example, by irradiation with at least one of ultraviolet light or an electron beam. In at least one embodiment of the present invention, the Group-III element nitride substrate is irradiated with energy higher than the bandgap energy of a constituent material for the channel layer. Through irradiation with such energy, for example, the occurrence of the leakage of current in the HEMT device can be satisfactorily predicted.

A light source that can emit laser light having a wavelength shorter than a band edge is used for the irradiation with ultraviolet light. Typically, a He—Cd laser or an excimer laser is used as a laser light source. In addition, for example, a deep ultraviolet (DUV) lamp, such as a low-pressure mercury lamp or a deuterium lamp, may also be used for the irradiation with ultraviolet light.

For example, an electron beam source (e.g., an electron gun) having an energy of from about 0.5 KeV to about 10 KeV is used for the irradiation with an electron beam. Examples of the electron beam source include a cold cathode field emission electron source, a photocathode electron source, and a Schottky electron source.

For example, a Group-III element nitride substrate including gallium nitride may be irradiated with ultraviolet light having a wavelength of 364 nm or less. A Group-III element nitride substrate including aluminum gallium nitride having bandgap energy higher than that of gallium nitride may require higher energy and hence may be irradiated with the electron beam.

The measurement of an emission spectrum obtained by irradiating the Group-III element nitride substrate with excitation energy may be typically performed by measuring the intensity of light having any appropriate wavelength, which is separated with a spectroscope, through use of any appropriate ultraviolet detector. Examples of the ultraviolet detector include a Si photodiode and a photomultiplier tube (PMT). In addition, an example of the ultraviolet detector is a spectral array detector obtained by combining a small grating with a CCD/CMOS/NMOS image sensor.

The half width of a band-edge emission peak is obtained from the measured emission spectrum. When the measured half width satisfies a predetermined value (or is a predetermined value or less), a semiconductor device excellent in quality can be obtained. For example, a HEMT device having leakage current suppressed can be obtained. In addition, the yield of the production of a semiconductor device can be significantly improved by selecting and using a Group-III element nitride substrate that may satisfy a predetermined half width. Here, the half width encompasses a full width at half maximum (FWHM) and a half width at half maximum (HWHM). In at least one embodiment of the present invention, the full width at half maximum of the band-edge emission peak of the measured emission spectrum is preferably 6.5 nm or less. In at least one embodiment of the present invention, the half width at half maximum on a long-wavelength side of the band-edge emission peak of the measured emission spectrum is preferably 4.2 nm or less.

The intensity of the emission spectrum obtained by irradiating the semi-insulating Group-III element nitride substrate with excitation energy may be weak as compared to the intensity of the emission spectrum obtained by irradiating a conductive Group-III element nitride substrate (e.g., a Group-III element nitride substrate that is not doped with an element except a Group-III element) with excitation energy, and further, is easily influenced by the surface flatness of the substrate and the presence or absence of an affected layer. However, the inventors of the present invention have closely examined the relationship between the emission spectrum of the semi-insulating Group-III element nitride substrate and the quality of a semiconductor device to be obtained, and as a result, have found that there is a relationship between the half width of the band-edge emission peak and the quality of the semiconductor device to be obtained. In a Group-III element nitride having a satisfactory semi-insulating property, the band-edge intensity of the emission spectrum may be weak, but the emission via various levels in the vicinity of the band edge is relatively decreased, with the result that the half width may appear narrow. Meanwhile, for example, when a donor impurity such as oxygen is incorporated into a Group-III element nitride crystal, the intensity of emission in the vicinity of the band edge is increased, and the half width may be increased.

The half width of the band-edge emission peak may be used to simply determine whether or not the Group-III element nitride substrate is satisfactory by the measurement at room temperature. In a precise sense, the emission spectrum may include emission from various levels in the vicinity of the band edge and can be observed separately only at extremely low temperatures, whereas the half width of the band-edge emission peak can be measured at room temperature. In addition, the measurement of the half width of the band-edge emission peak tends to be less dependent on a measuring apparatus. Specifically, it is not required to adjust the intensity of the excitation energy for irradiation to a constant value or to check reproducibility through use of a calibration sample.

The irradiation with excitation energy may be performed to a plurality of locations on the main surface of the Group-III element nitride substrate. When the plurality of locations are irradiated with the excitation energy for mapping of the half width of the band-edge emission peak on the surface of the substrate, it is possible to predict that the region having a half width that does not satisfy a predetermined value becomes a region in which the quality of a semiconductor device to be obtained is low (e.g., a defective region with large leakage current). For example, the disc-shaped substrate illustrated in FIG. 2 is irradiated with the excitation energy at predetermined intervals (e.g., intervals of from 0.01 mm to 1 mm) in each of longitudinal and transverse directions within its surface. Mapping data may be obtained from the resultant data of the half widths. The location for forming a semiconductor device may be selected based on the mapping data on the surface of the substrate.

### C. Production Method

A method of producing a Group-III element nitride substrate according to at least one embodiment of the invention includes: preparing a seed crystal substrate including a base substrate and a seed crystal film; and growing a Group-III element nitride crystal doped with an element except a Group-III element on the seed crystal film of the seed crystal substrate.

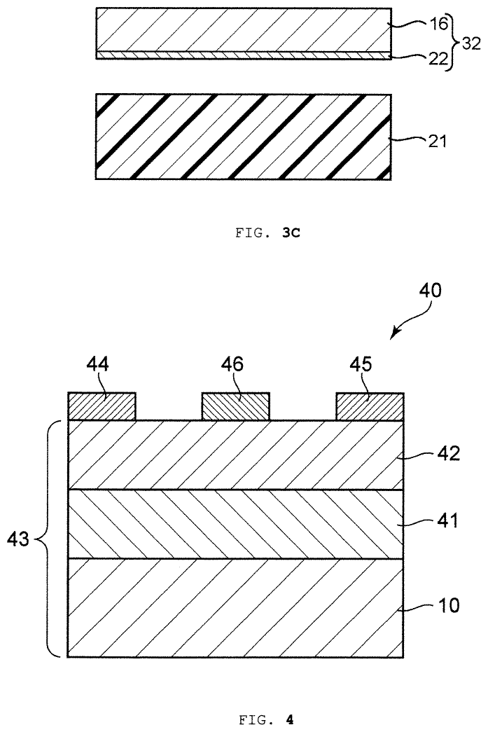

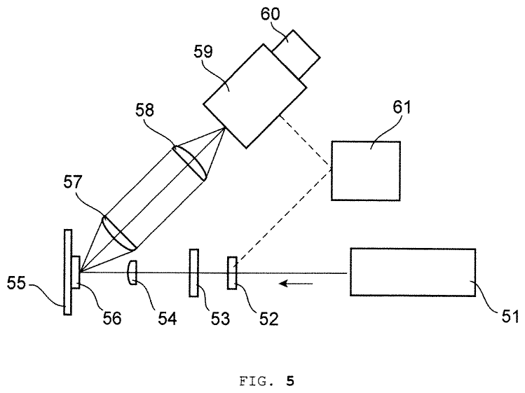

FIG. 3A to FIG. 3C are each a view for illustrating a production process for a Group-III element nitride substrate according to at least one embodiment of the present invention. In FIG. 3A, there is illustrated a state in which a seed crystal film 22 has been formed on an upper surface 21a of a base substrate 21 including the upper surface 21a and a lower surface 21b facing each other to complete a seed crystal substrate 20.

For example, a substrate having such a shape and size that a Group-III element nitride substrate having a desired shape and size can be produced is used as the base substrate. Typically, the base substrate has a disc shape having a diameter of from 50 mm to 200 mm. The thickness of the base substrate is, for example, from 200 μm to 800 μm.

Any appropriate substrate may be used as the base substrate. The base substrate preferably includes a monocrystalline body having a hexagonal crystal structure. For example, a sapphire substrate including single crystal alumina is preferably used as the base substrate.

The off-cut of the sapphire substrate may be set to any appropriate angle. The off-cut of the sapphire substrate is preferably 0.58° or less, more preferably 0.48° or less, still more preferably 0.42° or less. Through use of a sapphire substrate having such off-cut, for example, a Group-III element nitride substrate from which a semiconductor device excellent in quality can be produced in a high yield (e.g., at a high ratio of non-defective products) can be obtained. Meanwhile, the off-cut of the sapphire substrate is preferably 0.20° or more. Through use of a sapphire substrate having such off-cut, for example, a Group-III element nitride crystal can be satisfactorily grown. Here, the off-cut of the sapphire substrate means the angle of the tilt of the main surface of the sapphire substrate with respect to a reference crystal plane (c-plane).

The thickness of the seed crystal film is, for example, 0.2 μm or more. From the viewpoint of preventing meltback and disappearance of the seed crystal at the time of film formation (crystal growth), the thickness of the seed crystal film is preferably 1 μm or more, more preferably 2 μm or more. Meanwhile, from the viewpoint of productivity, the thickness of the seed crystal film is preferably 10 μm or less, more preferably 5 μm or less.

Any appropriate material may be adopted as a material for forming the seed crystal film. A Group-III element nitride is typically used as the material for forming the seed crystal film. Details of the Group-III element nitride are as described above. In at least one embodiment of the present invention, gallium nitride is used. Gallium nitride that is recognized to show yellow luminescence effect when observed with a fluorescence microscope is preferably used. In such gallium nitride, a peak (yellow luminescence (YL) or a yellow band (YB)) is observed in the range of from 2.2 eV to 2.5 eV in addition to an exciton transition (UV) from a band to another band.

The seed crystal film may be formed by any appropriate method. A vapor phase epitaxy method is typically used as a method of forming the seed crystal film. Specific examples of the vapor phase epitaxy method include a metal-organic chemical vapor deposition (MOCVD) method, a hydride vapor phase epitaxy (HVPE) method, a pulsed excitation deposition (PXD) method, a molecular-beam epitaxy (MBE) method, a vapor deposition method, and a sublimation method. Of those, a MOCVD method is preferably used.

The formation of the seed crystal film by the MOCVD method includes, for example, a first formation step and a second formation step in the stated order. Specifically, the first formation step includes forming a first layer (low-temperature grown buffer layer) (not shown) on the base substrate at a temperature T1 (e.g., from 450° C. to 550° C.), and the second formation step includes forming a second layer (not shown) at a temperature T2 (e.g., from 1,000° C. to 1,200° C.) higher than the temperature T1. The thickness of the first layer is, for example, from 20 nm to 50 nm. The thickness of the second layer is, for example, from 1 μm to 5 μm.

Next, a Group-III element nitride crystal is grown on the seed crystal film 22 of the seed crystal substrate 20 to form a Group-III element nitride crystal layer 16. Thus, a laminated substrate 30 is obtained as illustrated in FIG. 3B. The degree of growth of the Group-III element nitride crystal (thickness of the Group-III element nitride crystal layer 16) may be adjusted in accordance with a desired thickness of the Group-III element nitride substrate. Any appropriate direction may be selected as the growth direction of the Group-III element nitride crystal in accordance with, for example, usages or purposes. Specific examples thereof include: the normal direction of each of the above-mentioned c-plane, a-plane, and m-plane; and the normal direction of a plane tilted with respect to each of the above-mentioned c-plane, a-plane, and m-plane.

The Group-III element nitride crystal may be grown by any appropriate method. The method of growing the Group-III element nitride crystal is not particularly limited as long as a crystal direction substantially following the crystal direction of the above-mentioned seed crystal film can be achieved by the method. Specific examples of the method of growing the Group-III element nitride crystal include: vapor phase epitaxy methods, such as a metal-organic chemical vapor deposition (MOCVD) method, a hydride vapor phase epitaxy (HVPE) method, a pulsed excitation deposition (PXD) method, a molecular-beam epitaxy (MBE) method, and a sublimation method; and liquid phase epitaxy methods, such as a flux method, an ammonothermal method, a hydrothermal method, and a sol-gel method. Those methods may be used alone or in combination thereof.

The flux method (e.g., a Na flux method) is preferably adopted as the method of growing the Group-III element nitride crystal. Details of such growth method are described in, for example, Japanese Patent No. 5451085, and the growth may be performed by appropriately adjusting the various conditions of the described growth method. Specifically, the growth of the Group-III element nitride crystal may be performed by adjusting various conditions with a crystal-growing apparatus including a pressure-resistant vessel to which a pressurized nitrogen gas can be supplied, a rotary table that can rotate within the pressure-resistant vessel, and an outer vessel to be mounted on the rotary table.

The growth of the Group-III element nitride crystal by the flux method is typically performed with a crucible serving as a growth vessel. Specifically, the above-mentioned seed crystal substrate is placed at a predetermined position in the crucible, and further, raw materials are filled into the crucible. The crucible in which the seed crystal substrate is placed is typically, in a state of being closed with a lid, placed at specified pressure and temperature under an atmosphere containing nitrogen, and subjected to growth process.

The raw materials include, for example, a melt composition containing flux, a Group-III element, and a dopant. The flux preferably contains at least one of an alkali metal or an alkaline earth metal, and more preferably contains metal sodium. Typically, the flux and a metal material substance are mixed to be used. An elemental metal, an alloy, a metal compound, or the like may be used as the metal material substance, but the elemental metal is preferably used from the viewpoint of handling.

The crucible (including a lid) may be formed of any appropriate material that may be used in the flux method. Examples of the material for the crucible include alumina, yttria, and yttrium aluminum garnet (YAG). In addition, the material for the crucible may be a single crystal or a polycrystal (ceramics). The ceramics may be ceramics with so-called translucency having a relative density increased by hot isostatic pressing (HIP) treatment or the like.

The growth may be performed under the atmosphere containing nitrogen as described above. The growth atmosphere may contain other gases in addition to nitrogen. Inert gases, such as argon, helium, and neon, are preferably used as the other gases.

The pressure of the atmosphere during the growth may be set to any appropriate pressure. The pressure of the atmosphere during the growth is preferably 10 atm or more, more preferably 30 atm or more, for example, from the viewpoint of preventing the evaporation of the flux. Meanwhile, the pressure of the atmosphere during the growth is preferably 2,000 atm or less, more preferably 500 atm or less, for example, from the viewpoint of preventing the crystal-growing apparatus from becoming too large.

The temperature of the atmosphere during the growth may be set to any appropriate temperature. The temperature of the atmosphere during the growth is preferably from 700° C. to 1,000° C., more preferably from 800° C. to 900° C.

The growth is preferably performed while the crucible is rotated. For example, the crucible closed with a lid is placed in the outer vessel and mounted on the rotary table, and the crucible is rotated by rotating the rotary table.

After the growth of the Group-III element nitride crystal, as illustrated in FIG. 3C, the Group-III element nitride crystal (Group-III element nitride crystal layer 16) is separated from the base substrate 21 to provide a freestanding substrate 32. Typically, as illustrated in FIG. 3C, the freestanding substrate 32 may include the Group-III element nitride crystal layer 16 and the seed crystal film 22. The Group-III element nitride crystal may be separated from the base substrate by any appropriate method. As a method of separating the Group-III element nitride crystal, there are given, for example, a method of causing spontaneous separation from the base substrate by utilizing a thermal shrinkage difference between the Group-III element nitride crystal and the base substrate in a temperature decrease step after the growth of the Group-III element nitride crystal, a separation method including chemical etching, and a laser lift-off method including laser light irradiation. When the Group-III element nitride crystal is separated by the laser lift-off method, typically, laser light is applied from a lower surface 21b side of the base substrate 21 of the laminated substrate 30. In addition, the freestanding substrate may be obtained by grinding, or by cutting with a cutter such as a wire saw.

The freestanding substrate 32 may be used as it is for the above-mentioned Group-III element nitride substrate. However, typically, the freestanding substrate 32 may be subjected to any appropriate processing to provide the above-mentioned Group-III element nitride substrate.

An example of the processing to which the above-mentioned freestanding substrate is subjected is grinding (e.g., grinding with diamond abrasive grains) of its peripheral edge portion. Typically, the freestanding substrate is processed into the above-mentioned desired shape and size (e.g., a disc shape having a desired diameter) by grinding.

Another example of the processing to which the above-mentioned freestanding substrate is subjected is processing, such as grinding or polishing (e.g., lap polishing or chemical-mechanical polishing (CMP)), of its main surface (upper surface or lower surface). Typically, the freestanding substrate is thinned and flattened by the grinding and the polishing so as to have a desired thickness. In at least one embodiment of the present invention, the freestanding substrate may be brought into a state of the Group-III element nitride crystal layer 16 alone (a single crystal growth layer alone) by removing the seed crystal film 22 through the processing of the main surface.

In addition, examples of the processing to which the above-mentioned freestanding substrate is subjected include chamfering of its outer peripheral edge, removal of an affected layer, and removal of a residual stress that may result from the affected layer.

### D. Usage

The Group-III element nitride substrate may be applied to any appropriate semiconductor device. FIG. 4 is a schematic sectional view for illustrating the schematic configuration of a semiconductor device according to at least one embodiment of the present invention by using a HEMT device as an example. A HEMT device 40 includes a laminated structure 43 including the Group-III element nitride substrate 10, a channel layer 41, and a barrier layer 42 in the stated order, and a source electrode 44, a drain electrode 45, and a gate electrode 46 arranged on the laminated structure 43. Those electrodes may each be a metal electrode having a thickness of from about a little over ten nanometers to about a hundred and several tens of nanometers.

The laminated structure 43 may be obtained by subjecting the respective layers to heterojunction. For example, the channel layer 41 and the barrier layer 42 may be formed above the Group-III element nitride substrate 10 by epitaxial growth. The laminated structure is sometimes referred to as “epitaxial substrate.” The thickness of the channel layer 41 is, for example, from 50 nm to 5 μm. The thickness of the barrier layer 42 is, for example, from 2 nm to 40 nm.

The Group-III element nitride crystal may be adopted as each of materials for forming the channel layer 41 and the barrier layer 42. For example, gallium (Ga), aluminum (Al), or indium (In) is used as a Group-III element for forming a Group-III element nitride. Those elements may be used alone or in combination thereof. In at least one embodiment of the present invention, the Group-III element nitride substrate 10 may include gallium nitride doped with an element except Ga. In this case, the channel layer 41 preferably includes gallium nitride. In addition, the barrier layer 42 preferably includes at least one selected from aluminum gallium nitride, aluminum indium nitride, and aluminum indium gallium nitride.

The channel layer 41 and the barrier layer 42 may each be formed by any appropriate method. In at least one embodiment of the present invention, the channel layer 41 and the barrier layer 42 may each be formed by a MOCVD method. When the channel layer 41 and the barrier layer 42 are each formed by the MOCVD method, a metal-organic (MO) gas may be used as a Group-III element source. For example, when a gallium nitride layer and an aluminum gallium nitride layer are formed as the channel layer 41 and the barrier layer 42, respectively, by the MOCVD method, trimethyl gallium (TMG) and trimethyl aluminum (TMA) may be used as a Ga source and an Al source, respectively. In addition, an ammonia gas may be used as a nitrogen source. In addition, at least one of a hydrogen gas or a nitrogen gas may be used as a carrier gas.

Although not shown, a buffer layer may be arranged between the Group-III element nitride substrate 10 and the channel layer 41. For example, the buffer layer may be formed at the time of the formation of the channel layer and may include materials for forming the channel layer.

When the half width of the band-edge emission peak of the Group-III element nitride substrate 10 satisfies a predetermined value, for example, the leakage current can be satisfactorily suppressed in the HEMT device 40. The predetermined value may be, for example, a full width at half maximum of 6.5 nm or less, or a half width at half maximum on a long-wavelength side of 4.2 nm or less.

### EXAMPLES

The present invention is specifically described below by way of Examples, but the present invention is not limited to these Examples. A resistivity is a value measured by the following measurement method.

### <Resistivity>

A resistivity within a substrate surface was measured by a non-contact method using a time dependent charge amount. Specifically, the substrate was mounted on a stage of a capacitor including a probe and the stage, and the probe was brought close to the vicinity of the substrate. Then, a pulse voltage having a pulse width of 100 ns was applied, and the time dependent charge amount of the substrate was measured at room temperature (25° C.) for 1 second to calculate the resistivity.

### Experimental Example 1

### (Production of Seed Crystal Substrates)

c-Plane sapphire substrates each having a diameter of 3 inches with various off-cuts (0.20°, 0.28°, 0.36°, 0.39°, 0.42°, 0.43°, 0.44°, 0.46°, 0.48°, 0.52°, 0.56°, 0.58°, and 0.60°) were prepared. A gallium nitride film having a thickness of 2 μm was formed on each of the sapphire substrates by an MOCVD method to produce seed crystal substrates.

### (Growth of Gallium Nitride Crystals)

The growth of a gallium nitride crystal on each of the seed crystal substrates was performed with a crystal-growing apparatus including a pressure-resistant vessel to which a pressurized nitrogen gas can be supplied, a rotary table that can rotate in the pressure-resistant vessel, and an outer vessel to be mounted on the rotary table.

The resultant seed crystal substrates were placed in each alumina crucible in a glove box under nitrogen atmosphere. Next, 40 g of metal gallium, 80 g of metal sodium, and 0.1 g of iron serving as a doping element were each melted in the glove box and filled into each crucible. The seed crystal substrates were immersed in each flux melt, followed by the covering of the crucibles with alumina plates respectively. In this state, the crucibles were loaded into stainless steel-made inner vessels respectively, and the inner vessels were further loaded into a stainless steel-made outer vessel capable of holding the inner vessels, followed by the closing of the outer vessel with a lid provided with a nitrogen-introducing pipe. In this state, the outer vessel was mounted on the rotary table placed in a heating portion in the crystal-growing apparatus, which had been vacuum-baked in advance, and the pressure-resistant vessel of the crystal-growing apparatus was closed with a lid and hermetically sealed.

Subsequently, while the heating portion (including an upper heater, a middle heater, and a lower heater) was operated to heat a heating space so that its temperature became 850° C., a nitrogen gas was introduced into the pressure-resistant vessel from nitrogen gas cylinders until a pressure therein became 4 MPa, and the outer vessel was horizontally rotated. This state was held for 35 hours to grow a gallium nitride crystal on each of the seed crystal substrates.

Then, after the temperature was naturally cooled to room temperature and the pressure was reduced to atmospheric pressure, the lid of the alumina crucible was opened. As a result, the following state was established: the grown gallium nitride crystal and the sapphire substrate were spontaneously separated from each other. Thus, gallium nitride crystals each having a diameter of 3 inches and a thickness of 1 mm were obtained.

After that, in each of the resultant gallium nitride crystals, the peeled surface of the gallium nitride crystal from the sapphire substrate and the opposite surface thereto were flattened by polishing with diamond abrasive grains. Thus, Fe-doped gallium nitride substrates each having a diameter of 3 inches, a thickness of 0.5 mm, and a resistivity of 1×10⁷ Ω·cm or more were obtained.

### Experimental Example 2

Mn-doped gallium nitride substrates each having a diameter of 3 inches, a thickness of 0.5 mm, and a resistivity of 1×10⁷ Ω·cm or more were obtained in the same manner as in Experimental Example 1 except that Mn was used as the doping element instead of Fe (0.1 g of manganese was filled into the crucible).

### <Evaluation>

The gallium nitride substrates obtained in each of Experimental Example 1 and Experimental Example 2 were subjected to the following evaluations.

### 1. Half Width of Band-Edge Emission Peak (Full Width at Half Maximum and Half Width at Half Maximum)

Photoluminescence obtained by irradiating the resultant gallium nitride substrate with an ultraviolet laser light was subjected to spectrum measurement with a spectroscope to determine the half width of a band-edge emission peak.

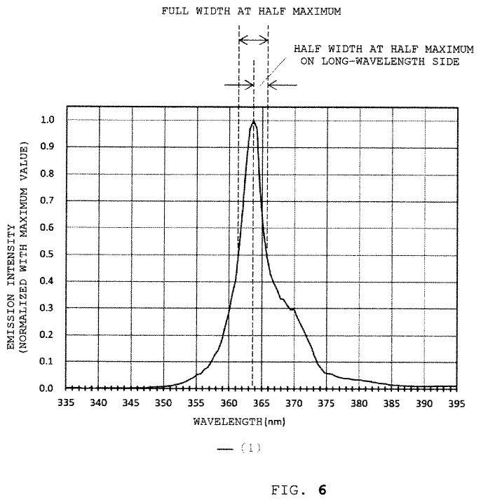

Specifically, as illustrated in FIG. 5, the gallium nitride substrate (measurement substrate) 56 to be obtained was fixed to a sample table 55, and the main surface of the substrate 56 was irradiated with a He—Cd laser light having a wavelength of 325 nm from a laser device 51 in this state. The laser irradiation was performed by applying the laser light to the main surface of the substrate 56 at an incident angle of 45° through a chopper 52, a light-reducing plate 53, and a condenser lens 54 of φ50 mm at a focal length of 100 mm. Photoluminescence from the substrate 56 was allowed to enter a spectroscope 59 through condenser lenses 57 and 58 of φ150 mm at a focal length of 100 mm. The arrow in FIG. 5 indicates the direction of the laser light.

A photodetector (photomultiplier tube) 60 was mounted on the spectroscope 59. A weak signal detected by the photodetector 60 was amplified by a lock-in amplifier 61 in synchronization with the chopper 52 to provide an emission spectrum. The position of the sample table 55 to which the substrate 56 was to be fixed was adjusted so that the detection intensity of the lock-in amplifier 61 was maximized. In this case, the diameter of the irradiation light on the substrate 56 was about 00.3 mm. In addition, the dashed line in FIG. 5 indicates a synchronization signal.

A band-edge emission was measured at intervals of 1 mm in the surface of the substrate by moving the sample table 55, and the half width of a peak value was calculated to provide mapping data of the half width of the band-edge emission peak.

### 2. Leakage Current

### (Production of Epitaxial Substrate)

A gallium nitride (GaN) layer and an aluminum gallium nitride (AlGaN) layer were epitaxially grown on the main surface of each resultant gallium nitride substrate by the MOCVD method to produce an epitaxial substrate. Specifically, the resultant gallium nitride substrate was placed on a susceptor in an MOCVD furnace. The inside of the MOCVD furnace was set to a mixed flow of a hydrogen gas and a nitrogen gas, and increased in temperature to 1, 100° C. at the furnace internal pressure of 0.3 atm. After the temperature reached 1, 100° C., a GaN layer having a thickness of 1 μm was formed through use of an ammonia gas and a Ga source gas. After that, an AlGaN layer (composition ratio of Al to Ga of 0.2:0.8) having a thickness of 20 nm was formed by further adding an Al source gas. Thus, an epitaxial substrate was formed. After the formation of the layers, the temperature of the substrate was decreased to room temperature, and the pressure was restored to atmospheric pressure. Then, the epitaxial substrate was removed from the MOCVD furnace.

### (Production of Transistor Device)

Next, a transistor device was produced through use of each epitaxial substrate. Prior to the formation of electrodes on each epitaxial substrate, a silicon oxide film having a thickness of 10 nm was formed as a passivation film on each resultant epitaxial substrate. Subsequently, the silicon oxide film was removed by etching at locations in which a source electrode, a drain electrode, and a gate electrode were to be formed by photolithography.

Next, the AlGaN layer and the GaN layer were removed by etching to a depth of about 400 nm at a site to be a boundary between the respective transistor devices to be obtained by photolithography and a reactive ion etching (RIE) method.

Next, a photoresist was applied onto the AlGaN layer, and openings were formed in regions in which the source electrode and the drain electrode were to be formed by photolithography. Then, metal films of Ti, Al, Ni, and Au were sequentially formed to thicknesses of 25 nm, 75 nm, 15 nm, and 100 nm, respectively, by a vacuum vapor deposition method to form a multilayer structure. After that, each substrate was immersed in an organic solvent or a peeling liquid, and the photoresist film was removed by lift-off. Thus, the source electrode and the drain electrode were obtained. Then, each substrate was subjected to heat treatment at 850° C. for 30 seconds under a nitrogen gas atmosphere from the viewpoint of improving the ohmic properties of the source electrode and the drain electrode.

Subsequently, in the same manner as in the formation of the source electrode and the drain electrode, metal films of Pt and Au were sequentially formed to thicknesses of 30 nm and 100 nm, respectively, by photolithography and a vacuum vapor deposition method to form a gate electrode that may be in a Schottky metal pattern.

Thus, a transistor device in which the electrodes having a gate width of 1 mm, an interval between the source and the gate of 2 μm, an interval between the gate and the drain of 8 μm, and a gate length of 1 μm were formed was produced.

A leakage current was measured in any appropriately selected 16 samples in each epitaxial substrate among the transistor devices produced as described above. The current flowing between the source and the drain when a voltage of 10 V was applied as a source-drain voltage and a gate voltage was set to −4 V to provide an off-state was defined as the leakage current.

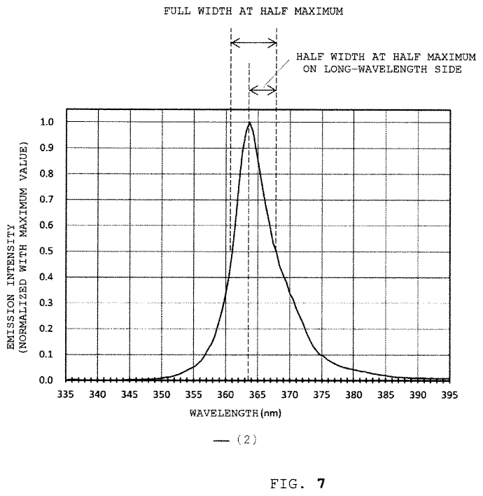

As an example, Table 1, FIG. 6, and FIG. 7 show the evaluation results of the case in which the sapphire substrate having an off-cut of 0.43° in Experimental Example 1 was used. Specifically, Table 1 summarizes the leakage current of each of any appropriately selected 16 devices in the substrate, and the full width at half maximum and half width at half maximum on a long-wavelength side of the band-edge emission peak of each of the devices at a position in the substrate, which were determined from the above-mentioned mapping data.

In addition, the emission spectrum in the vicinity of the band edge (wavelength: 364 nm) corresponding to a device with a low leakage current (4.57×10⁻⁸ A/mm²) at the time of an off-state is shown by the line (1) in FIG. 6, and the emission spectrum in the vicinity of the band edge corresponding to a device with a high leakage current (6.85×10⁻² A/mm²) is shown by the line (2) in FIG. 7. The emission spectrum was normalized with a maximum value.

TABLE 1

| Full width at half | Half width at half maximum | Leakage |
|---|---|---|
| maximum of band-edge | on long-wavelength side of | current |
| emission peak (nm) | band-edge emission peak (nm) | (A/mm²) |
| 4.03 | 2.30 | 7.01 × 10⁻⁹ |
| 4.12 | 2.22 | 7.48 × 10⁻⁹ |
| 4.22 | 2.40 | 1.75 × 10⁻⁸ |
| 4.28 | 1.93 | 3.33 × 10⁻⁸ |
| 4.30 | 2.10 | 1.13 × 10⁻⁸ |
| 4.34 | 2.09 | 4.57 × 10⁻⁸ |
| 4.95 | 2.81 | 6.76 × 10⁻⁸ |
| 5.50 | 3.30 | 7.12 × 10⁻⁸ |
| 6.20 | 3.85 | 2.84 × 10⁻⁷ |
| 6.26 | 3.92 | 3.52 × 10⁻⁷ |
| 6.40 | 4.02 | 6.35 × 10⁻⁷ |
| 6.50 | 4.15 | 8.55 × 10⁻⁷ |
| 6.60 | 4.26 | 6.82 × 10⁻⁴ |
| 6.77 | 4.29 | 1.17 × 10⁻² |
| 6.84 | 4.32 | 6.85 × 10⁻² |
| 7.03 | 4.55 | 2.42 × 10⁻¹ |

From Table 1, the ratio of non-defective products in the case of using the sapphire substrate having an off-cut of 0.43° is 75%, when a device having a leakage current of less than 1×10⁻⁶ A/mm² is defined as a non-defective product.

Similarly, the ratio of non-defective products in each of the gallium nitride substrates produced through use of the sapphire substrates having different off-cuts in Experimental Example 1 was calculated. The calculation results are summarized in Table 2.

TABLE 2

| Off-cut of sapphire | Ratio of non-defective |
|---|---|
| substrate (°) | products (%) |
| 0.20 | 100 |
| 0.28 | 100 |
| 0.36 | 94 |
| 0.39 | 88 |
| 0.42 | 88 |
| 0.43 | 75 |
| 0.44 | 44 |
| 0.46 | 31 |
| 0.48 | 25 |
| 0.52 | 19 |
| 0.56 | 13 |
| 0.58 | 6 |
| 0.60 | 0 |

As an example, Table 3 shows the evaluation results of the case in which the sapphire substrate having an off-cut of 0.43° in Experimental Example 2 was used. Specifically, Table 3 summarizes the leakage current of each of any appropriately selected 16 devices in the substrate, and the full width at half maximum and half width at half maximum on a long-wavelength side of the band-edge emission peak of each of the devices at a position in the substrate, which were determined from the above-mentioned mapping data.

TABLE 3

| Full width at half | Half width at half maximum | Leakage |
|---|---|---|
| maximum of band-edge | on long-wavelength side of | current |
| emission peak (nm) | band-edge emission peak (nm) | (A/mm²) |
| 4.18 | 2.26 | 5.18 × 10⁻⁹ |
| 4.47 | 2.58 | 2.00 × 10⁻⁹ |
| 4.84 | 2.91 | 3.13 × 10⁻⁹ |
| 4.94 | 3.12 | 5.25 × 10⁻⁹ |
| 5.47 | 3.44 | 9.16 × 10⁻⁹ |
| 5.85 | 3.64 | 2.20 × 10⁻⁸ |
| 6.40 | 3.78 | 4.52 × 10⁻⁸ |
| 6.42 | 4.00 | 2.43 × 10⁻⁷ |
| 6.45 | 4.06 | 5.01 × 10⁻⁷ |
| 6.50 | 4.12 | 7.35 × 10⁻⁷ |
| 6.70 | 4.31 | 6.12 × 10⁻⁶ |
| 6.81 | 4.49 | 7.78 × 10⁻⁶ |
| 6.89 | 4.53 | 3.16 × 10⁻⁵ |
| 6.92 | 4.50 | 4.20 × 10⁻⁵ |
| 7.21 | 4.65 | 4.04 × 10⁻⁴ |
| 7.40 | 4.63 | 2.67 × 10⁻³ |

From Table 3, the ratio of non-defective products in the case of using the sapphire substrate having an off-cut of 0.43° is 63%, when a device having a leakage current of less than 1×10⁻⁶ A/mm² is defined as a non-defective product.

Similarly, the ratio of non-defective products in each of the gallium nitride substrates produced through use of the sapphire substrates having different off-cuts in Experimental Example 2 was calculated. The calculation results are summarized in Table 4.

TABLE 4

| Off-cut of sapphire | Ratio of non-defective |
|---|---|
| substrate (°) | products (%) |
| 0.20 | 94 |
| 0.28 | 94 |
| 0.36 | 94 |
| 0.39 | 88 |
| 0.42 | 88 |
| 0.43 | 63 |
| 0.44 | 44 |
| 0.46 | 13 |
| 0.48 | 13 |
| 0.52 | 6 |
| 0.56 | 6 |
| 0.58 | 6 |
| 0.60 | 0 |

The Group-III element nitride substrate according to at least one embodiment of the present invention may be utilized as, for example, each of the substrates of various semiconductor devices.

According to at least one embodiment of the present invention, the Group-III element nitride substrate that can improve the yield of a semiconductor device can be provided.

What is claimed is:

1. A method of inspecting a Group-III element nitride substrate, the method comprising:
preparing a Group-III element nitride substrate doped with an element except a Group-III element;
irradiating the Group-III element nitride substrate with excitation energy; and
measuring a half width of a band-edge emission peak of an emission spectrum obtained by the irradiation.

2. The inspection method according to claim 1, wherein the irradiating the Group-III element nitride substrate with the excitation energy is performed by irradiation with at least one of ultraviolet light or an electron beam.

3. The inspection method according to claim 1, wherein the element except the Group-III element includes a transition element.

4. The inspection method according to claim 3, wherein the transition element includes at least one of iron or manganese.

5. The inspection method according to claim 1, wherein the Group-III element nitride substrate contains gallium nitride.

6. The inspection method according to claim 1, wherein the Group-III element nitride substrate has a resistivity determined by measuring a time dependent charge amount of 1×10⁵ Ω·cm or more.

7. The inspection method according to claim 1, wherein the half width is a full width at half maximum.

8. The inspection method according to claim 1, wherein the half width is a half width at half maximum.

9. A method of producing a Group-III element nitride substrate, the method comprising:
performing the method of inspecting a Group-III element nitride substrate of claim 1; and
selecting the Group-III element nitride substrate based on the half width of the band-edge emission peak.

10. The method of producing a Group-III element nitride substrate according to claim 9, wherein the Group-III element nitride substrate having a full width at half maximum of the band-edge emission peak of 6.5 nm or less is selected.

11. The method of producing a Group-III element nitride substrate according to claim 9, wherein the Group-III element nitride substrate having a half width at half maximum on a long-wavelength side of the band-edge emission peak of 4.2 nm or less is selected.

12. The method of producing a Group-III element nitride substrate according to claim 9,
wherein the preparing the Group-III element nitride substrate includes:
preparing a seed crystal substrate including a sapphire substrate including an upper surface and a lower surface facing each other, and a seed crystal film to be formed on the upper surface of the sapphire substrate; and
growing a Group-III element nitride crystal doped with an element except a Group-III element on the seed crystal film of the seed crystal substrate, and
wherein the sapphire substrate has an off-cut of 0.58° or less.

13. The method of producing a Group-III element nitride substrate according to claim 12, wherein the sapphire substrate has an off-cut of 0.200 or more and 0.42° or less.

14. A method of producing a semiconductor device, the method comprising:
irradiating a Group-III element nitride substrate doped with an element except a Group-III element with excitation energy, and measuring a half width of a band-edge emission peak of an emission spectrum obtained by the irradiation;
forming a channel layer and a barrier layer on the Group-III element nitride substrate to provide a laminated structure; and
arranging a source electrode, a drain electrode, and a gate electrode on the laminated structure,
wherein the Group-III element nitride substrate is irradiated with energy higher than bandgap energy of a constituent material for the channel layer, and
wherein the laminated structure is obtained by epitaxial growth.

15. A Group-III element nitride substrate doped with an element except a Group-III element,
the Group-III element nitride substrate having a full width at half maximum of a band-edge emission peak of an emission spectrum obtained by irradiation with excitation energy of 6.5 nm or less, or having a half width at half maximum on a long-wavelength side of the band-edge emission peak of the emission spectrum obtained by the irradiation with the excitation energy of 4.2 nm or less.

16. The Group-III element nitride substrate according to claim 15, wherein the Group-III element nitride substrate contains gallium nitride.

17. The Group-III element nitride substrate according to claim 15, wherein the element except the Group-III element includes a transition element.

18. The Group-III element nitride substrate according to claim 17, wherein the transition element includes at least one of iron or manganese.

19. A method of producing the Group-III element nitride substrate of claim 15, the method comprising:
preparing a seed crystal substrate including a sapphire substrate including an upper surface and a lower surface facing each other, and a seed crystal film to be formed on the upper surface of the sapphire substrate; and
growing a Group-III element nitride crystal doped with an element except a Group-III element on the seed crystal film of the seed crystal substrate,
wherein the sapphire substrate has an off-cut of 0.58° or less.

20. The method of producing the Group-III element nitride substrate according to claim 19, wherein the Group-III element nitride crystal is grown by a flux method.
